(19) United States
(12) Patent Application Publication
(10) Pub. No.: US 2006/0024870 A1
(43) Pub. Date: Feb. 2, 2006

(54) Manufacturing method for low temperature polycrystalline silicon cell

(76) Inventors: Wen-Chun Wang, Taichung City (TW); Ming-Chang Yu, Taichung City (TW); Chien-Chung Kuo, Fongyuan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/898,948

(22) Filed: Jul. 27, 2004

(51) Int. Cl. H01L 21/00

(52) U.S. Cl. 438/166

(57) ABSTRACT

A manufacturing method for low temperature polycrystalline silicon cell, including steps of: forming a buffer layer on a substrate; depositing a-Si:H on the buffer layer; baking and dehydrogenating the a-Si:H; melting and crystallizing the a-Si into Poly-Si by means of laser; defining a Poly-Si island via photolithography; depositing a gate oxide; plating a metal layer on the gate oxide; defining the regions of the gate metal and data line metal by means of photolithography; implanting semiconductor impurites with the gate serving as a mask to define the source/drain; forming a passivation; etching the passivation to form contact holes; filling transparent conductive material into the contact holes to accomplish the connection between the source/drain and data line; and forming the pattern of pixel electrode to achieve the low temperature polycrystalline silicon cell.

### BACKGROUND OF THE INVENTION

The present invention is related to a manufacturing method for low temperature polycrystalline silicon cell, which is simplified and can achieve low temperature polycrystalline silicon cell with better crystallinity and properties.

FIGS. 4A to 4E show a manufacturing procedure of a conventional low temperature polycrystalline silicon cell by way of bottom gate. Aluminum or molybdenum is sputtered on a substrate 80. Then the metal layer is etched by means of photolithography to form a gate 81, a source 82 and a drain 83 as shown in FIG. 4A. Then, by means of chemical vapor deposition (CVD), a gate oxide 84 and a-Si:H are deposited. The a-Si is molten by means of laser to crystallize into Poly-Si 85. Then, a Poly-Si island is pattern-etched by a photolithography process as shown in FIG. 4B. Then, by way of back exposure, with the gate 81, source 82 and drain 83 serving as a mask, N⁺ impurities are implanted as shown in FIG. 4C. After removing the photoresistor, a passivation 86 is deposited and etched to form contact holes 87 as shown in FIG. 4D. Then ITO 88 is filled into the contact holes 87 to accomplish connection between S/D and data line. Finally, the pattern of pixel electrode is formed as shown in FIG. 4E to achieve the low temperature polycrystalline silicon cell.

In the structure of the low temperature polycrystalline silicon cell made by way of bottom gate, the Poly-Si is formed on upper side of the gate 81. Therefore, the a-Si is deposited on the metallic gate 81. Laser is projected onto the a-Si to melt and crystallize the a-Si. In such procedure, the metallic gate 81 with better heat conductivity will conduct and dissipate the heat. Therefore, the Poly-Si will have smaller grain size and the mobility is lower. Accordingly, the low temperature polycrystalline silicon cell will have poorer properties.

### SUMMARY OF THE INVENTION

It is therefore a primary object of the present invention to provide a manufacturing method for low temperature polycrystalline silicon cell, which is simplified and can achieve low temperature polycrystalline silicon cell with better crystallinity and properties.

According to the above object, the manufacturing method for low temperature polycrystalline silicon cell of the present invention includes steps of:
forming a buffer layer on a substrate, then a layer of a-Si:H being further deposited on the buffer layer, then the a-Si:H being baked by means of a high temperature baker and dehydrogenated, then the a-Si being molten by means of laser to crystallize the a-Si into Poly-Si, then a Poly-Si island being formed by photolithography, then a gate oxide being deposited;
sputtering a metal layer on the gate oxide, the regions of the gate metal and data line metal being defined by means of photolithography;
implanting semiconductor N⁺ impurities with the gate serving as a mask to define the regions of the source/drain;
forming a passivation, then the regions of the source/drain and data line electrode being etched to form contact holes; and
filling transparent conductive material into the contact holes to accomplish the connection between the source/drain and data line, finally, the pattern of pixel electrode being formed to achieve the low temperature polycrystalline silicon cell.

The Poly-Si is formed under the gate. Therefore, when using the laser to melt and crystallize the a-Si into Poly-Si, the Poly-Si will have better crystallinity and the properties of the low temperature polycrystalline silicon cell are enhanced.

The TFT low temperature polycrystalline silicon cell of top gate pattern can be made only by means of four masks. Therefore, the manufacturing procedure is simplified.

The present invention can be best understood through the following description and accompanying drawings wherein:

### BRIEF DESCRIPTION OF THE DRAWINGS

FIGS. 1A to 1E show the manufacturing procedure of a first embodiment of the present invention;

FIGS. 2A to 2F show the manufacturing procedure of a second embodiment of the present invention;

FIGS. 3A to 3F show the manufacturing procedure of a third embodiment of the present invention; and

FIGS. 4A to 4E show the manufacturing procedure of a conventional low temperature polycrystalline silicon cell.

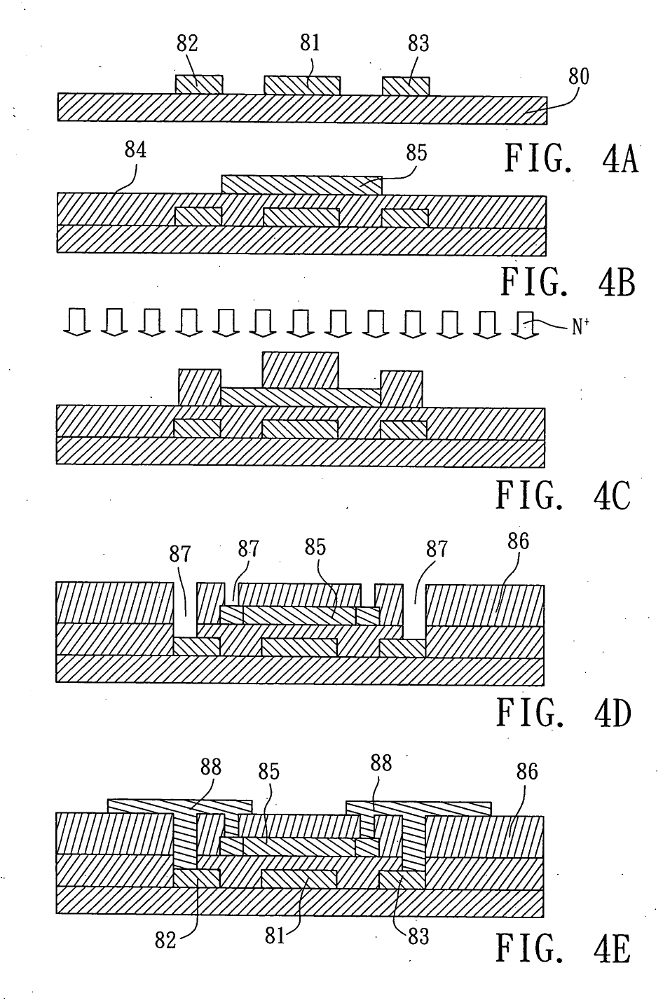

### DETAILED DESCRIPTION OF THE PREFERRED EMBODIMENTS

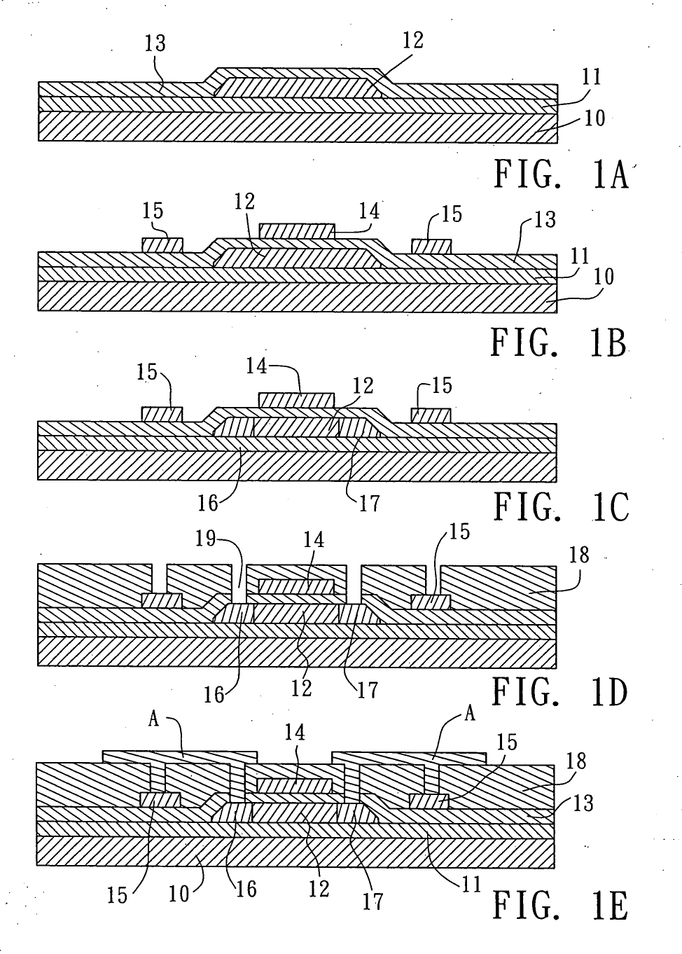

Please refer to FIGS. 1A to 1E. With manufacturing method for PMOS (p-type transistor) or NMOS (n-type transistor) exemplified, the manufacturing method for low temperature polycrystalline silicon cell of the present invention includes steps of:
1. fully depositing and forming a buffer layer 11 over the substrate 10 as shown in FIG. 1A, the buffer layer 11 being made of SiO₂, SiN_{X}, TEOS oxide, etc. a layer of a-Si:H being further deposited on the buffer layer 11 with a thickness of about 500˜1500 Å, then the a-Si:H being baked for 2˜4 hrs by means of a high temperature baker at 400° C.˜500° C. and dehydrogenated, then the a-Si being molten by means of laser to crystallize the a-Si into Poly-Si, then a Poly-Si island 12 being formed by photolithography, then by means of chemical vapor deposition (CVD), a gate oxide 13 being deposited with a thickness of about 500˜2000 Å as shown in FIG. 1A;
2. depositing MoW on the gate oxide 13 with a thickness of 1000˜3000 Å by sputtering, the regions of the gate metal 14 and data line metal 15 being defined by means of photolithography as shown in FIG. 1B;
3. implanting N⁺ or P⁺ with the gate serving as a mask to define the regions of the source 16/drain 17 as shown in FIG. 1C;
4. forming silicon oxide or silicon nitride or TEOS oxide as a passivation 18 by means of CVD, the passivation 18 having a thickness of 3000˜5000 Å, by photolithography, the regions of the source/drain and data line electrode being etched to form contact holes 19 as shown in FIG. 1D; and
5. filling low resistance transparent conductive material A (such as ITO, IZO, etc.) into the contact holes 19 to accomplish the connection between the source/drain and data line, finally, the pattern of pixel electrode being formed as shown in FIG. 1E to achieve the low temperature polycrystalline silicon cell.

In the structure of the low temperature polycrystalline silicon cell of the present invention, the Poly-Si is formed under the gate to form a top gate pattern. Therefore, when using the laser to melt and crystallize the a-Si into Poly-Si, it is avoided that the metallic gate with better heat conductivity conducts and dissipates the heat. Therefore, the Poly-Si will have larger grain size and better mobility. Accordingly, The Poly-Si has better crystallinity and the properties of the low temperature polycrystalline silicon cell are enhanced.

In conclusion, the manufacturing method of the present invention has the following advantages:
1. The crystallized Poly-Si will have larger grain size and better mobility. Accordingly, the Poly-Si has better crystallinity and the properties of the low temperature polycrystalline silicon cell are enhanced.
2. The TFT low temperature polycrystalline silicon cell of top gate pattern can be made only by means of four masks. The manufacturing procedure is simplified.

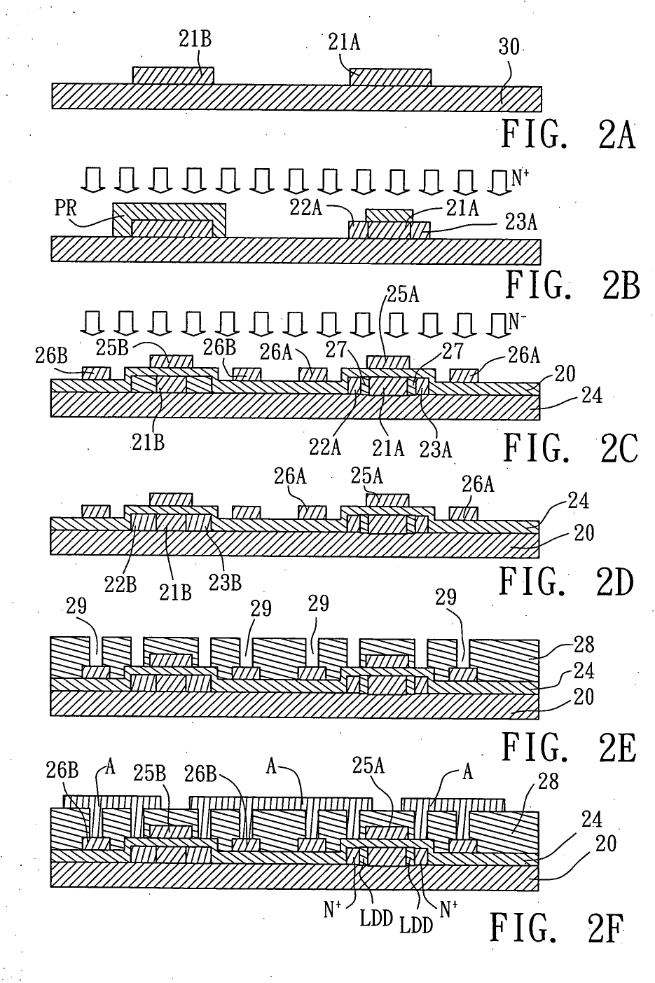

FIGS. 2A to 2F show a second embodiment of the present invention. With the manufacturing method for CMOS with LDD exemplified, the manufacturing method for low temperature polycrystalline silicon cell of the present invention includes steps of:
1. depositing a layer of SiO₂ with a thickness of 2000˜5000 Å on the substrate 20 as a buffer layer as shown in FIG. 2A, then a-Si:H with a thickness of 500˜1500 Å being further deposited on the SiO₂ by means of CVD, then the a-Si:H film being subjected to a dehydrogenation treatment through heating preferably at 400˜550° C., then the a-Si being molten by means of laser to crystallize the a-Si into Poly-Si, then two Poly-Si islands 21A, 21B being defined by photolithography;
2. implanting N⁺ as shown in FIG. 2B, phosphorus being implanted into the regions of n-type source 22A/drain 23A;
3. depositing gate oxide 24 by means of CVD as shown in FIG. 2C, the material of the gate oxide being silicon oxide or silicon nitride or TEOS oxide;
4. depositing MoW (1000˜3000 Å) on the gate oxide 24 by means of sputtering, then the regions of the gate metal 25A, 25B and data line metal 26A, 26B being defined by means of photolithography, then N⁻ being implanted with the gate metal 25A and data line metal 26A serving as a mask to form the region of the LDD 27;
5. implanting P⁺ as shown in FIG. 2D, boron being implanted into the regions of p-type source 22A/drain 23A;
6. forming silicon oxide or silicon nitride or TEOS oxide on the gate electrode and data line electrode as a passivation 28 by means of CVD as shown in FIG. 2E, the passivation 28 having a thickness of 3000˜5000 Å, by means of photolithography, the regions of the source/drain and data line electrode being etched to form contact holes 29; and
7. filling transparent conductive material A (such as ITO, IZO, etc.) into the contact holes 29 to accomplish the connection between the source/drain and data line as shown in FIG. 2F, finally, the pattern of pixel electrode being formed.

The second embodiment of the present invention is applicable to the low temperature polycrystalline silicon cell of CMOS. The second embodiment can also achieve better crystallinity and simplify the manufacturing procedure of the Poly-Si as the first embodiment.

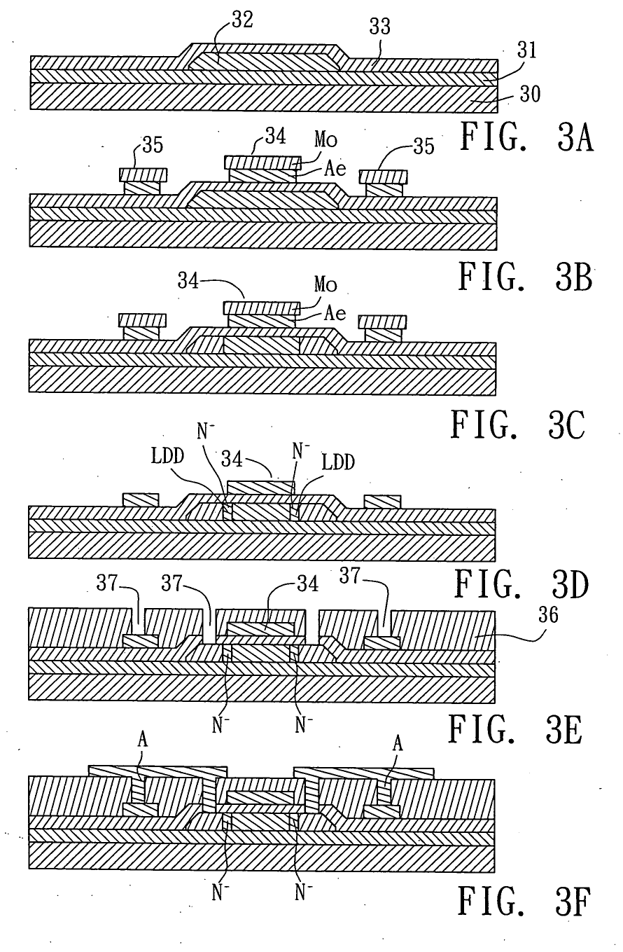

FIGS. 3A to 3F show a third embodiment of the present invention. With the manufacturing method for NMOS with LDD exemplified, the manufacturing method for low temperature polycrystalline silicon cell of the present invention includes steps of:
1. depositing a-Si:H with a thickness of 500˜1000 Å on the buffer layer 31 of the substrate 30, which buffer-layer 31 can be made of SiO₂, SiNₓ, TEOS oxide, etc. as shown in FIG. 3A, then the a-Si:H film being subjected to a dehydrogenation treatment through heating preferably at 400˜550° C., then the a-Si being molten by means of laser to crystallize the a-Si into Poly-Si, then a Poly-Si island 32 being defined by photolithography, then gate oxide 33 with a thickness of 500˜2000 Å being deposited by means of CVD;
2. sequentially depositing Al/Cr, Cr/Al or Al/Mo on the gate oxide 24 by means of sputtering as shown in FIG. 3B, in this embodiment, Al/Mo being exemplified, then the regions of the gate metal 34 and data line metal 35 being defined by means of photolithography, due to the difference between the etching rates of the etching liquid with respect to the two kinds of metals, a gap of 0.5˜1.5 μm being formed between the upper layer of Mo and lower layer of Al;
3. with the upper layer of Mo serving as a mask, implanting phosphorus to form N⁺ region as shown in FIG. 3C;
4. after etching Mo, with the Al serving as a mask, forming N⁻ LDD region as shown in FIG. 3D;
5. depositing a passivation layer 36 on gate electrode and data line electrode as shown in FIG. 3E to define the regions of contact holes 37; and
6. filling low resistance transparent conductive material A (such as ITO, IZO, etc.) into the contact holes 37 to accomplish the connection between the source/drain and data line as shown in FIG. 3F, finally, the pattern of pixel electrode being formed.

The third embodiment can also achieve better crystallinity and simplify the manufacturing procedure of the Poly-Si as the first embodiment.

The above embodiments are only used to illustrate the present invention, not intended to limit the scope thereof. Many modifications of the above embodiments can be made without departing from the spirit of the present invention.

What is claimed is:

1. A manufacturing method for low temperature polycrystalline silicon cell, the low temperature polycrystalline silicon cell comprising a substrate, a buffer layer, Poly-Si island, gate oxide, gate metal, data line metal, passivation and transparent conductive material which are sequentially overlaid on the substrate, said manufacturing method comprising steps of:
forming a buffer layer on a substrate, then a layer of a-Si:H being further deposited on the buffer layer, then the a-Si:H film being subjected to a dehydrogenation treatment through heating preferably at 400˜550° C., then the a-Si being molten by means of laser to crystallize the a-Si into Poly-Si, then a Poly-Si island being defined by photolithography, then a gate oxide being deposited;
sputtering a metal layer on the gate oxide, the regions of the gate metal and data line metal being defined by photolithography;
implanting semiconductor impurities with the gate serving as a mask to define the regions of the source/drain;
forming a passivation, then the regions of the source/drain and data line electrode being etched to form contact holes; and
filling transparent conductive material into the contact holes to accomplish the connection between the source/drain and data line, finally, the pattern of pixel electrode being formed to achieve the low temperature polycrystalline silicon cell.

2. The manufacturing method for low temperature polycrystalline silicon cell as claimed in claim 1, wherein the buffer layer is made of SiO₂, SiNₓ, TEOS oxide, etc.

3. The manufacturing method for low temperature polycrystalline silicon cell as claimed in claim 1, wherein the deposited a-Si:H has a thickness of about 500˜1000 Å.

4. The manufacturing method for low temperature polycrystalline silicon cell as claimed in claim 1, wherein the a-Si:H is baked in the high temperature baker for 2˜4 hrs at 400° C.˜500° C. and dehydrogenated.

5. The manufacturing method for low temperature polycrystalline silicon cell as claimed in claim 1, wherein the gate oxide is deposited with a thickness of about 500˜2000 Å by means of chemical vapor deposition (CVD).

6. The manufacturing method for low temperature polycrystalline silicon cell as claimed in claim 1, wherein in the step of sputtering the metal layer on the gate oxide, the metal layer is MoW which is deposited on the gate oxide with a thickness of 1000˜3000 Å by means of sputtering.

7. The manufacturing method for low temperature polycrystalline silicon cell as claimed in claim 1, wherein the passivation is formed by means of CVD and the material of the passviation is silicon oxide or silicon nitride or TEOS oxide, the passivation having a thickness of 3000˜5000 Å.

8. The manufacturing method for low temperature polycrystalline silicon cell as claimed in claim 1, wherein the transparent conductive material is ITO, IZO or the like.

9. The manufacturing method for low temperature polycrystalline silicon cell as claimed in claim 1, wherein in the step of sputtering the metal layer on the gate oxide, an upper metal layer and a lower metal layer of Al/Cr, Cr/Al or Al/Mo are sequentially deposited on the gate oxide by means of sputtering, due to the difference between the etching rates of the two metal layers, a gap being formed between the upper and lower metal layers, with the upper metal layer serving as a mask, phosphorus being implanted to form N⁺ region, then, immediately after etching the upper metal layer, with the lower metal layer serving as a mask, N⁻ LDD region being formed.

10. The manufacturing method follow temperature polycrystalline silicon cell as claimed in claim 1, wherein phosphorus is implanted in the regions of n-type source/drain, then N⁻ being implanted with the gate metal and data line metal serving as a mask to form LDD region, then boron being implanted in the regions of p-type source/drain to form CMOS with LDD.
